(19) United States
(12) Patent Application Publication
(10) Pub. No.: US 2012/0313208 A1
(43) Pub. Date: Dec. 13, 2012

(54) IMAGE SENSOR AND METHOD OF FORMING THE SAME

(76) Inventors: Sang-Hoon KIM, Seongnam-si (KR); Byungjun PARK, Yongin-si (KR); Junemo KOO, Suwon-si (KR); Seung-Hun SHIN, Suwon-si (KR); Gil-Sang YOO, Bucheon-si (KR)

(21) Appl. No.: 13/444,172

(22) Filed: Apr. 11, 2012

(30) Foreign Application Priority Data
Jun. 7, 2011 (KR) 10-2011-0054445

(51) Int. Cl. H01L 27/146

(52) U.S. Cl. 257/435; 257/E27.13

(57) ABSTRACT

An image sensor and a method of forming the same, where the image sensor may include a substrate including a pixel region and a pad region, a through via configured to penetrate the substrate in the pad region, a plurality of unit pixels in the pixel region, and a light shielding pattern between the plurality of unit pixels. The through via and the light shielding pattern include a same material.

### CROSS-REFERENCE TO RELATED APPLICATIONS

This U.S. non-provisional patent application claims priority under 35 U.S.C. §119 of Korean Patent Application No. 10-2011-0054445, filed on Jun. 7, 2011, the entire contents of which are hereby incorporated by reference.

### BACKGROUND

Example embodiments relate to an image sensor and method of forming the same, more particularly, a backside illuminated image sensor and method of forming the same.

In fabricating an image sensor, e.g., a CMOS image sensor, transistors may be formed on a semiconductor substrate which has photodiodes for each pixel thereon. A plurality of metal lines and interlayer dielectric layers may be formed on the transistors, and color filters and micro lens may be formed on the interlayer dielectric layers.

Light may pass through a plurality of the interlayer dielectric layers and may be reflected or blocked by the metal lines while traveling from the micro lens to the photodiodes. Therefore, images from the image sensor may become dark.

### SUMMARY

Example embodiments provide an image sensor capable of preventing or reducing cross-talk between unit pixels. Example embodiments also provide a method of forming an image sensor that is a simplified process.

According to example embodiments, an image sensor may include a substrate including a pixel region and a pad region, a through via configured to penetrate the substrate in the pad region, a plurality of unit pixels in the pixel region, and a light shielding pattern between the plurality of unit pixels, wherein the through via and the light shielding pattern include a same material.

The light shielding pattern may have a grid shape. An optical black region may surround the pixel region of the substrate, and an optical black pattern may be in the optical black region. The optical black pattern may include the same material as the through via. The substrate may include a first surface and a second surface opposite to the first surface. A first dielectric layer may be on the first surface, and the light shielding pattern may penetrate the first dielectric layer.

The optical black pattern may be on the first dielectric layer. The optical black pattern may penetrate the first dielectric layer. The through via may extend to penetrate the first dielectric layer. A pad may be configured to contact the through via on the first dielectric layer. An anti-refractive layer may be between the first dielectric layer and the substrate. The light shielding pattern and the optical black pattern may be configured to penetrate the anti-refractive layer and contact the substrate.

A second dielectric layer may be on the second surface, and a plurality of interconnects may be in the second dielectric layer. The through via may be configured to penetrate the first dielectric layer, the substrate, and a portion of the second dielectric layer to be electrically connected to the plurality of interconnects. The through via may contact an interconnect of the plurality of interconnects nearest to the second surface.

A reference pixel may be in the substrate in the optical black region. The optical black pattern may be configured to overlap the reference pixel. A plurality of transistors may be on the second surface, and light may be incident to the first surface. A device isolation layer may be in the pixel region of the substrate, and may separate the plurality of unit pixels. The light shielding pattern may overlap the device isolation layer in a vertical direction when viewed from a cross-sectional view.

According to example embodiments, an image sensor may include a substrate including an optical black region and a pad region, a through via penetrating the substrate in the pad region, and an optical black pattern in the optical black region. The optical black pattern and the through via may include a same material.

According to example embodiments, an image sensor may include a substrate including a pixel region and a pad region, a through via configured to penetrate the substrate in the pad region, a plurality of unit pixels in the pixel region, and an isolation structure including a light shielding pattern and a device isolation layer separating the plurality of unit pixels. The light shielding pattern may overlap the device isolation layer in a vertical direction when viewed from a cross-sectional view.

The light shielding pattern may have a grid shape. The through via and the light shielding pattern may include a same material. An optical black region may surround the pixel region of the substrate, and an optical black pattern may be in the optical black region. The optical black pattern may include the same material as the through via and the light shielding pattern.

### BRIEF DESCRIPTION OF THE DRAWINGS

The accompanying drawings are included to provide a further understanding of the inventive concepts, and are incorporated in and constitute a part of this specification. The drawings illustrate example embodiments and, together with the description, serve to explain principles of the inventive concepts. In the drawings:

FIG. 1 is a plan view of an image sensor according to example embodiments;

FIG. 2 is a cross-sectional view of an image sensor according to example embodiments taken along I-I′ line of FIG. 1;

FIGS. 3 through 12 are cross-sectional views illustrating a method of fabricating the image sensor according to example embodiments;

FIG. 13 is a cross-sectional view of an image sensor according to example embodiments taken along I-I′ line of FIG. 1;

FIG. 14 is a cross-sectional view of an image sensor according to example embodiments taken along I-I′ line of FIG. 1;

FIGS. 15 through 20 are cross-sectional views illustrating a method of fabricating the image sensor according to example embodiments;

FIG. 21 is a cross-sectional view of an image sensor according to example embodiments taken along I-I′ line of FIG. 1;

FIG. 22 is a cross-sectional view of an image sensor according to example embodiments taken along I-I′ line of FIG. 1; and

FIG. 23 is a block diagram illustrating an electronic device including an image sensor according to example embodiments.

### DETAILED DESCRIPTION OF EXAMPLE EMBODIMENTS

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

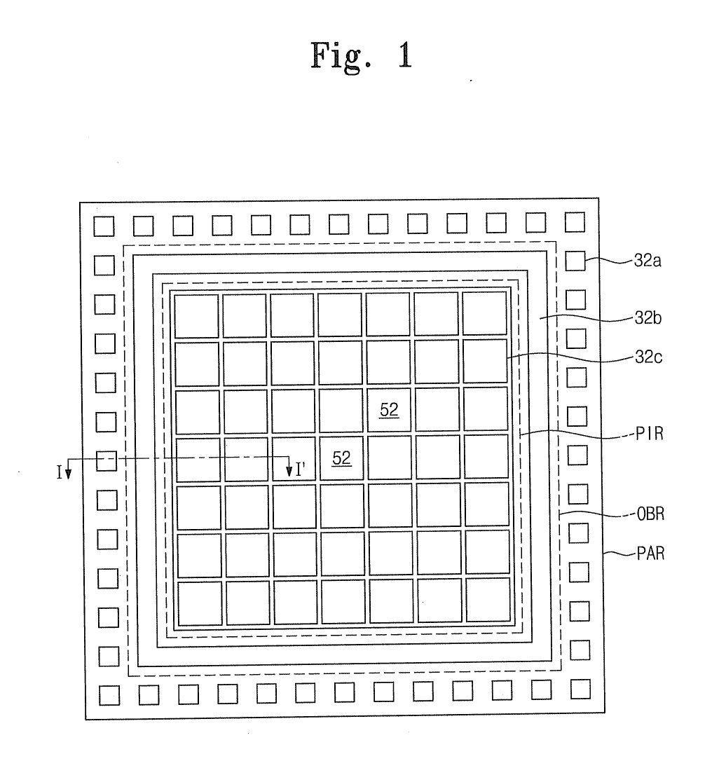

FIG. 1 is a plan view of an image sensor according to example embodiments.

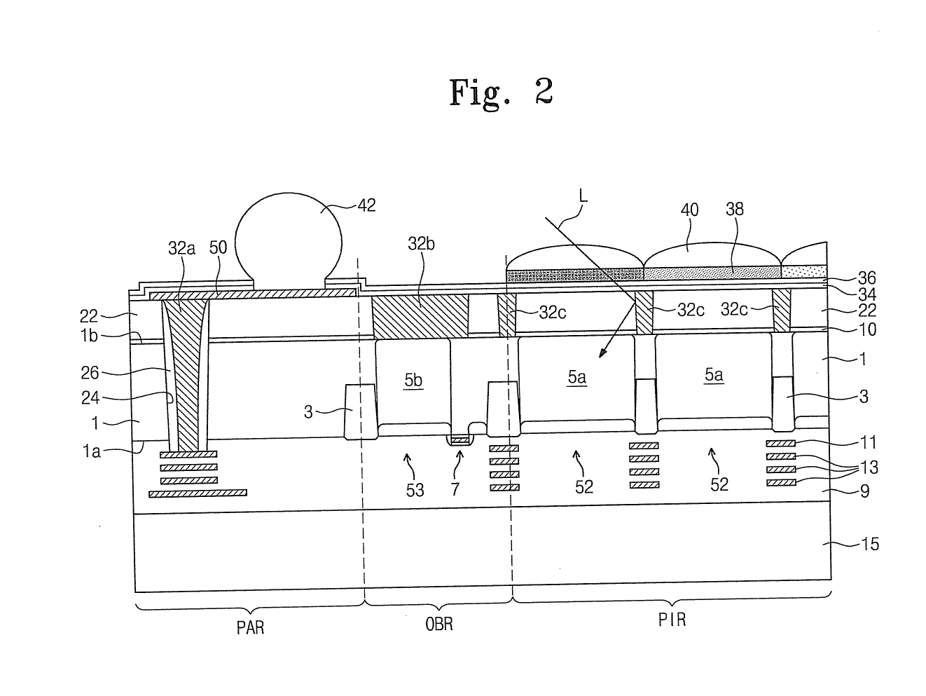

FIG. 2 is a cross-sectional view of an image sensor according to example embodiments taken along I-I″ line of FIG. 1.

Referring to FIGS. 1 and 2, an image sensor may include a substrate 1. For example, the substrate 1 may include a single silicon crystal or silicon epitaxial layer thereon. The substrate 1 may comprise a pixel region PIR including a plurality of unit pixels, an optical black region OBR surrounding the pixel region PIR, and a pad region PAR. The substrate 1 may include a second surface 1a, and a first surface 1b opposite to the second surface 1a. For example, the second surface 1a may be a front-side surface of the substrate 1, and the first surface 1b may be a back-side surface of the substrate 1. A plurality of unit pixels 52 may be disposed in the pixel region PIR. A unit photodiode 5a may be disposed in the substrate 1 for each of the unit pixels 52. Unit transistors (not shown) may be disposed on the second surface 1a to transfer charges generated from the unit photodiode 5a.

A device isolation layer 3 may be disposed adjacent to the second surface 1a between the unit pixels 52, and between the regions PIR, OBR, and PAR. A reference pixel 53 may be disposed in the optical black region OBR. The reference pixel 53 may include a reference photodiode 5b in the substrate 1 and a reference transistor 7 for transferring charges generated from the reference photodiode 5b. The unit and reference photodiodes 5a, 5b may include a p-type doped region and n-type doped region.

The second surface 1a of the substrate 1 may be covered with a second dielectric layer 9. The second dielectric layer 9 may include a plurality of interlayer dielectric layers. A first interconnect 11 nearest to the second surface 1a and second interconnects 13 spaced apart from the first interconnect 11 may be disposed in the second dielectric layer 9. A supporting substrate 15 may be attached on the second dielectric layer 9. An anti-refractive layer 10 may be disposed on the first surface 1b. A first dielectric layer 22 may be disposed on the anti-refractive layer 10. The anti-refractive layer 10 may include a non-organic material, e.g., a silicon nitride layer and/or a tantalum oxide layer.

A via hole 24 exposing the first interconnect 11 may be fanned by sequentially etching the first dielectric layer 22, the anti-refractive layer 10, the substrate 1 and a portion of the second dielectric layer 9.

A through via 32a may be formed in the via hole 24, and may penetrate the first dielectric layer 22, the anti-refractive layer 10, and at least a portion of the second dielectric layer 9 to contact the first interconnect 11. A dielectric spacer 26 may be disposed between the through via 32a and the first dielectric layer 22, between the through via 32a and the anti-refractive layer 10, and between the through via 32a and the second dielectric layer 9. The dielectric spacer 26 may be a spacer shaped dielectric layer. A diffusion barrier layer (not illustrated) may be disposed between the through via 32a and the dielectric spacer 26. The diffusion barrier layer may include, e.g., titanium, a titanium nitride layer, tantalum, and/or a tantalum nitride layer. A pad 50 may be in contact with the through via 32a in the pad region PAR. The pad 50 may include the same material as the through via 32a. In example embodiments, the pad 50 may include a different material, e.g., aluminum.

An optical black pattern 32b may be disposed in the optical black region OBR. The optical black pattern 32b may penetrate the first dielectric layer 22 and the anti-refractive layer 10 to be in contact with the first surface 1b. The optical black pattern 32b may cover the reference pixel 53, more specifically, the reference photodiode 5b. The optical black pattern 32b may block incident light to the reference pixel 53. A quantity of electric charge generated from the reference photodiode 5b when incident light are blocked may be transferred and sensed by the reference transistor 7. The quantity of electric charge may be considered as a reference electric charge. The reference electric charge may be compared with a unit electric charge transferred from the unit transistor. Signals sensed from each of the unit pixels 52 may be calculated from a difference between the unit electric charge and the reference electric charge.

A light shielding pattern 32c may be disposed in the pixel region PIR. For example, the light shielding pattern 32c may be disposed between the unit pixels 52 in the pixel region PIR. In example embodiments, the light shielding pattern 32c may expose areas between the unit pixels 52 and the reference pixel 53. The light shielding pattern 32c may penetrate the first dielectric layer 22 and the anti-refractive layer 10 to be in contact with the substrate 1. The light shielding pattern 32c may have a grid shape as illustrated in FIG. 1. The light shielding pattern 32c may vertically overlap the device isolation layer 3. The light shielding pattern 32c may reflect an oblique light L (incident toward an adjacent unit pixel) to each of the unit pixels 52. Thus, a cross-talk between the unit pixels 52 may be prevented or reduced.

The through via 32a, the optical black pattern 32b, and the light shielding pattern 32c may include a same material, e.g., tungsten. The optical black pattern 32b and the light shielding pattern 32c may be in contact with the first surface 1b of the substrate 1 to ground the substrate 1.

A protective layer 34 and a planarization layer 36 may be formed sequentially on the first dielectric layer 22. A color filter 38 overlapping the unit pixels 52 may be disposed on the planarization layer 36 in the pixel region PIR. A micro lens 40 may be disposed on the color filter 38. A terminal 42 may penetrate the protective layer 34 and the planarization layer 36 to contact the pad 50 in the pad region PAR. The terminal 42 may be, e.g., a solder ball or a bump. In example embodiments, a wire may be bonded on the pad 50.

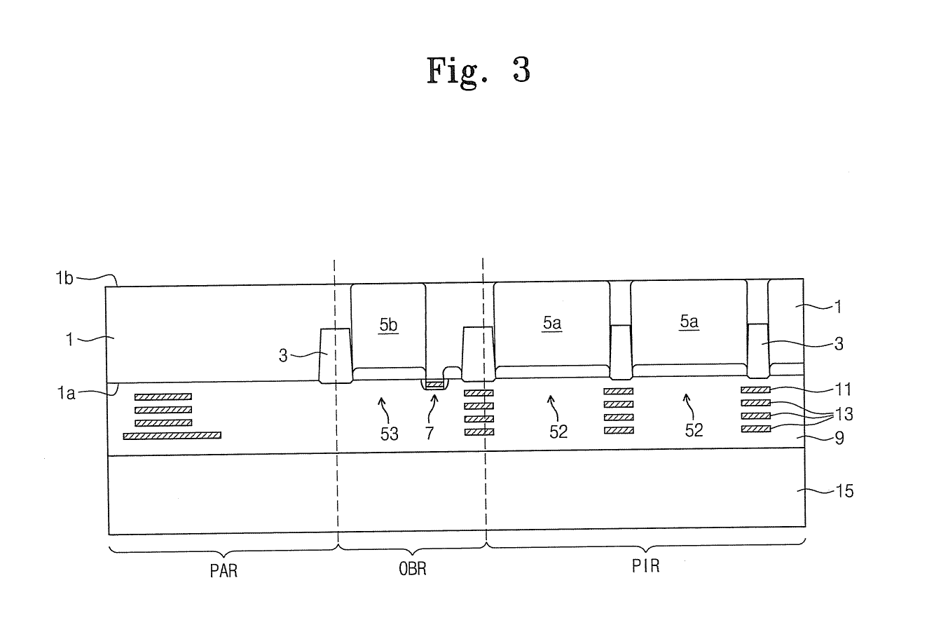

FIGS. 3 through 12 are cross-sectional views illustrating a method of fabricating the image sensor according to example embodiments.

Referring to FIG. 3, a substrate 1 including a pixel region PIR, an optical black region OBR, and a pad region PAR may be prepared. The substrate 1 may include a second surface 1a and a first surface 1b. A device isolation layer 3 may be formed near the second surface 1a to define the regions PIR, OBP, and PAR and to separate unit pixels 52 and a reference pixel 53. A unit photodiode 5a and a reference photodiode 5b may be formed in the substrate 1 using a process, e.g., ion implantation. A reference transistor 7 may be formed on the second surface 1a of the substrate 1. A second dielectric layer 9 may be formed on the second surface 1a of the substrate 1. A first interconnect 11 and a plurality of layers of second interconnects 13 may be formed in the second dielectric layer 9. After attaching a supporting substrate 15 to the second dielectric layer 9, the photodiodes 5a and 5b may be exposed by grinding a portion of the first surface 1b of the substrate 1.

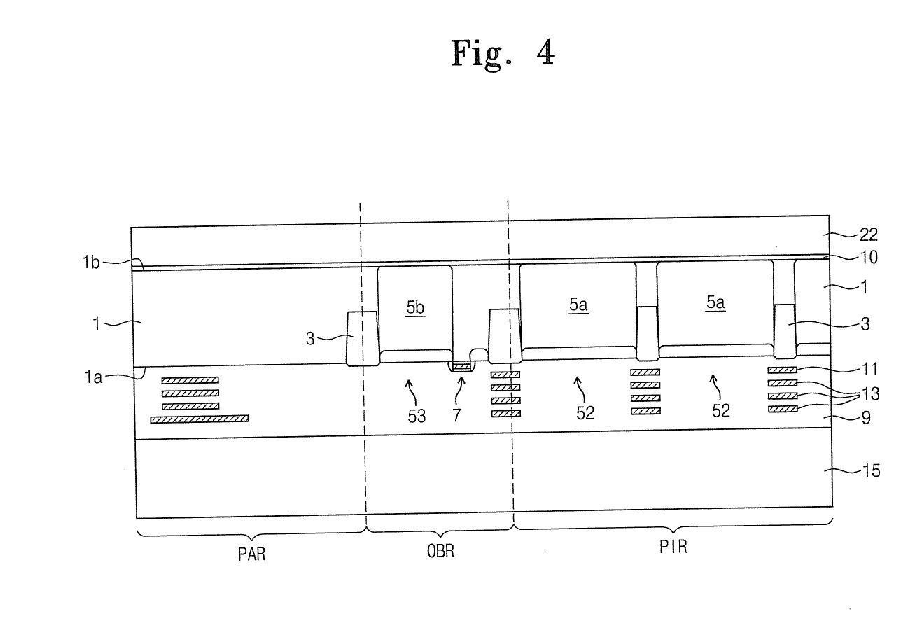

Referring to FIG. 4, an anti-refractive layer 10 and a first dielectric layer 22 may be formed on the first surface 1b of the substrate 1. The anti-refractive layer 10 may be formed of, e.g., a silicon nitride layer and/or a tantalum oxide layer. The first dielectric layer 22 may be formed of, e.g., a silicon oxide layer, silicon nitride layer, and/or silicon oxinitride layer.

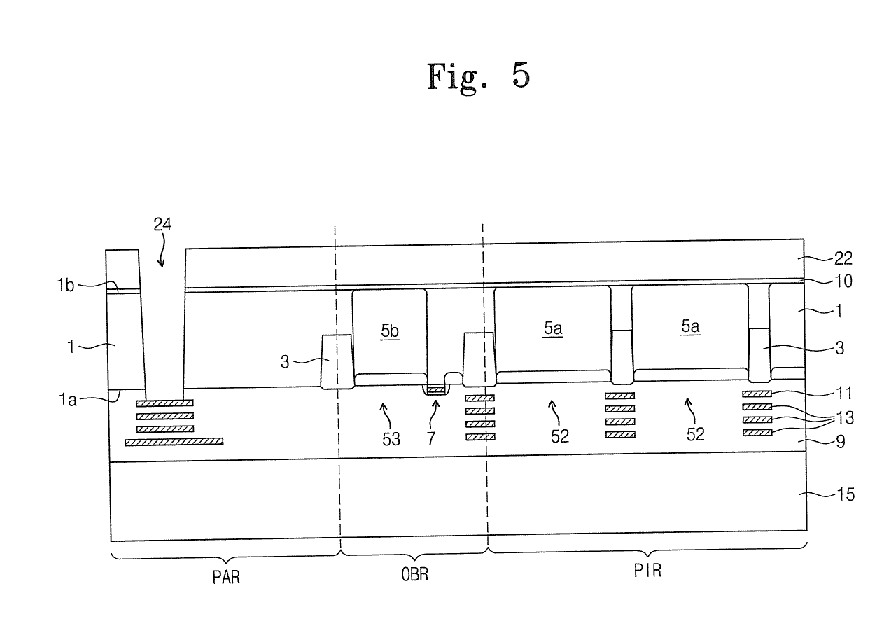

Referring to FIG. 5, a via hole 24 exposing the first interconnect 11 may be formed by sequentially etching the first dielectric layer 22, the anti-refractive layer 10, the substrate 1 and a portion of the second dielectric layer 9.

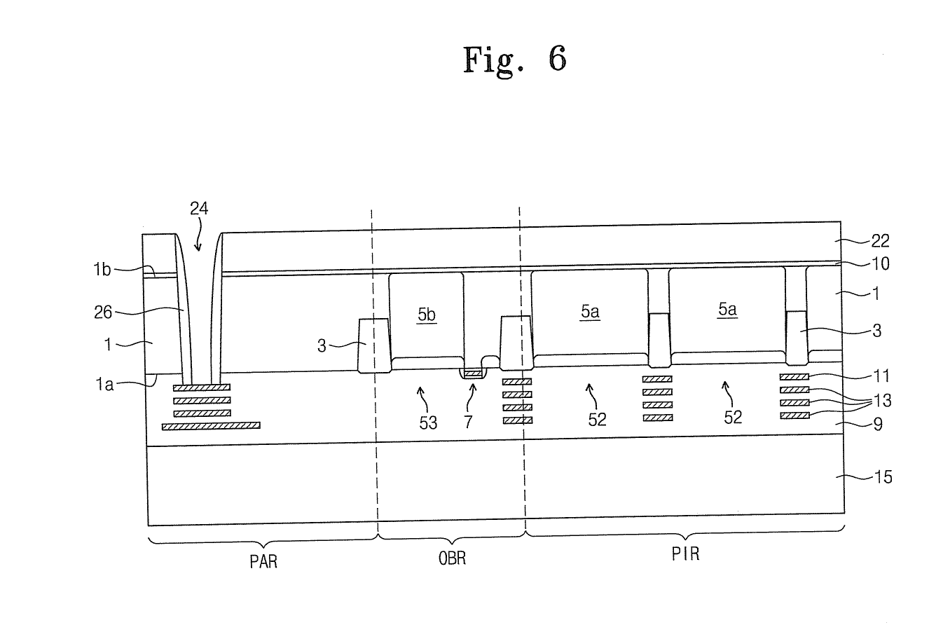

Referring to FIG. 6, a dielectric spacer 26 may be fog wed to cover the inner wall of the via hole 24. The dielectric spacer 26 may be formed of, e.g., oxide and/or nitride. A dielectric layer (not illustrated) may be conformally formed on the first surface 1b and anisotropically etched to form the dielectric spacer 26.

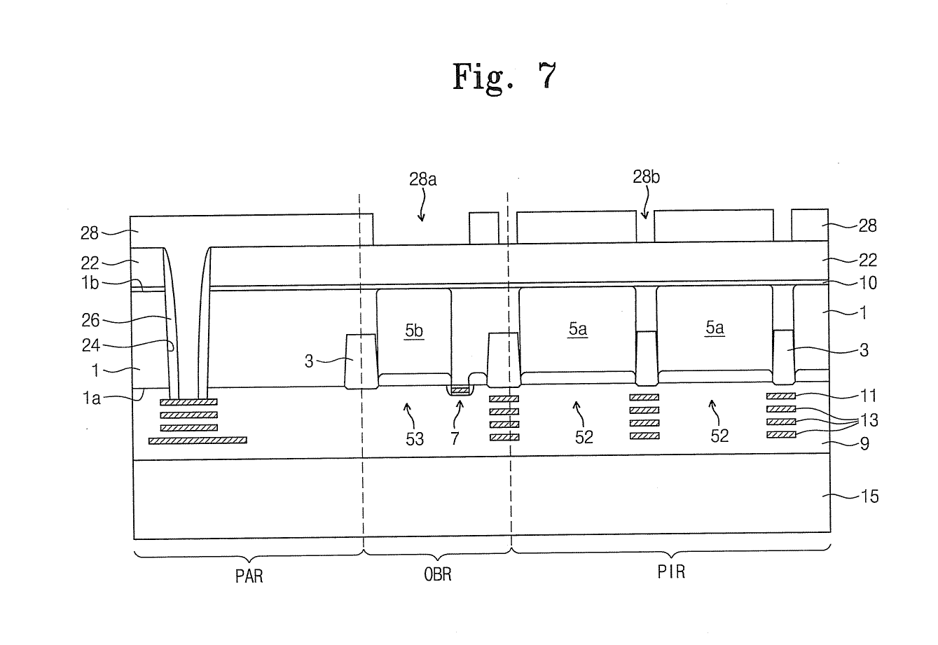

Referring to FIG. 7, a mask pattern 28 may be formed on the first dielectric layer 22. The mask pattern 28 may cover the pad region PAR. The mask pattern 28 may include a first opening 28a defining an optical black pattern described below in the optical black region OBR and a second opening 28b defining a light shielding pattern described below in the pixel region PIR. The mask pattern 28 may be formed of, e.g., a photo resist pattern.

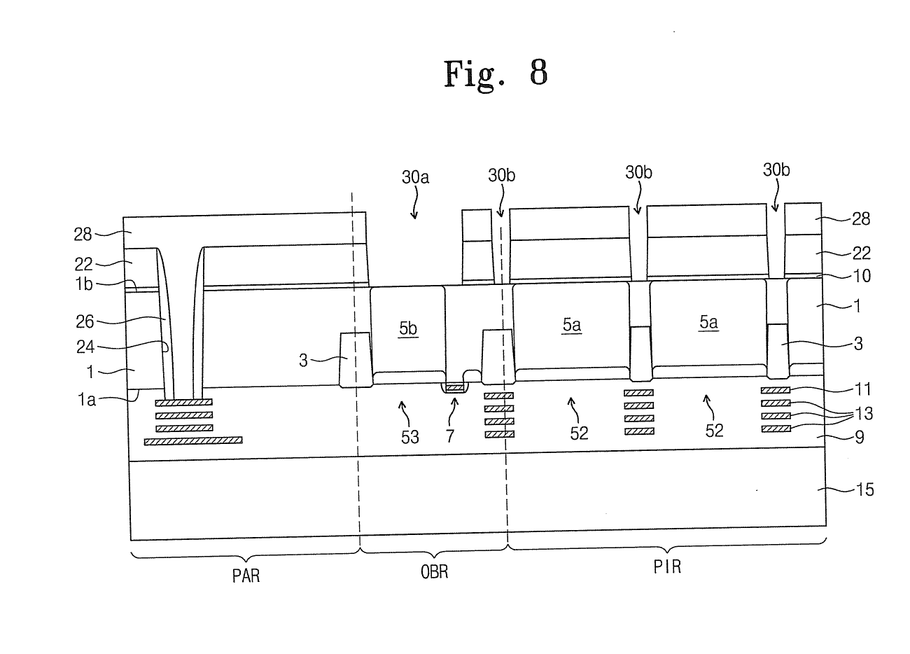

Referring to FIG. 8, the first surface 1b of the substrate 1 may be exposed by sequentially etching the first dielectric layer 22 and the anti-refractive layer 10 using the mask pattern 28 as an etching mask. Therefore, an optical black groove 30a corresponding to the first opening 28a and a light shielding groove 30b may be formed in the first dielectric layer 22 and the anti-refractive layer 10. The optical black groove 30a may be formed to have a closed loop shape, e.g., quadrangle, surrounding the pixel region PIR in plan view. The light shielding groove 30b may be formed to have a grid shape in a plan view as illustrated in FIG. 1.

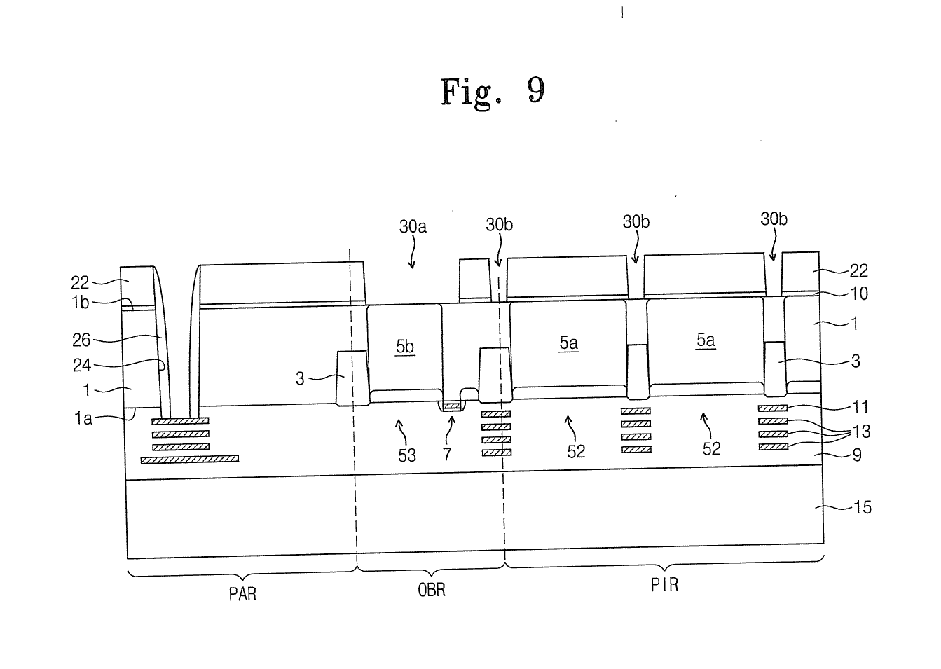

Referring to FIG. 9, the mask pattern 28 may be removed. When the mask pattern 28 is made of a photo resist, the mask pattern 28 may be removed by an ashing process. The dielectric spacer 26 in the via hole 24 and the first interconnect 11 at the bottom of the via hole 24 may be exposed by removing the mask pattern 28.

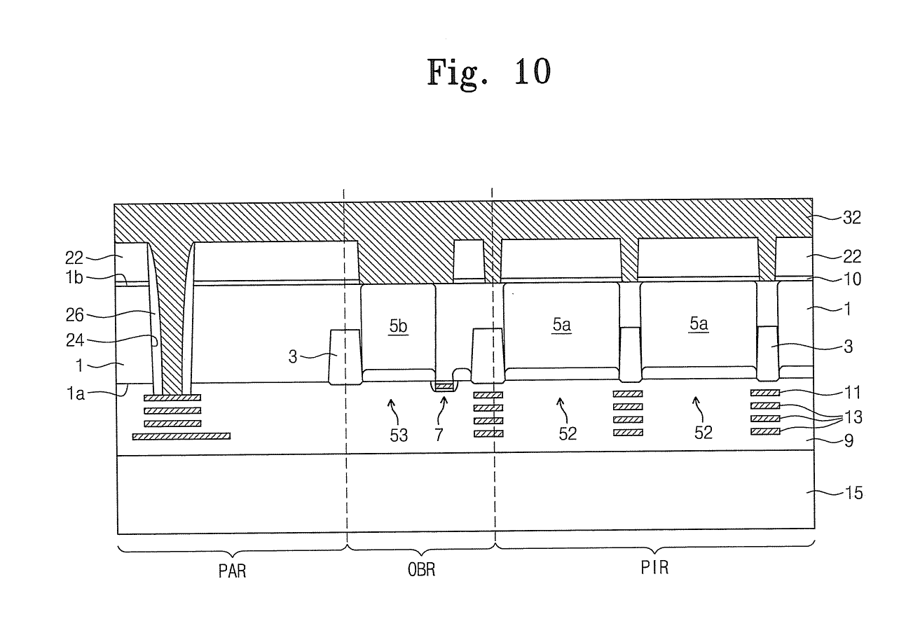

Referring to FIG. 10, a conductive layer 32 may be formed to fill the via hole 24, the optical black groove 30a, and the light shielding groove 30b. The conductive layer 32 may include, e.g., a tungsten layer. A seed layer and/or a diffusion barrier layer may be conformally formed before forming the conductive layer 32. The conductive layer 32 may be formed by a plating process and/or a deposition process. The conductive layer 32 may entirely fill the via hole 24 and the optical black groove 30a as illustrated in FIG. 10. In example embodiments, the conductive layer 32 may be conformally formed at a thickness of filling the light shielding groove 30b, not filling an entire space of the via hole 24 and the optical black groove 30a.

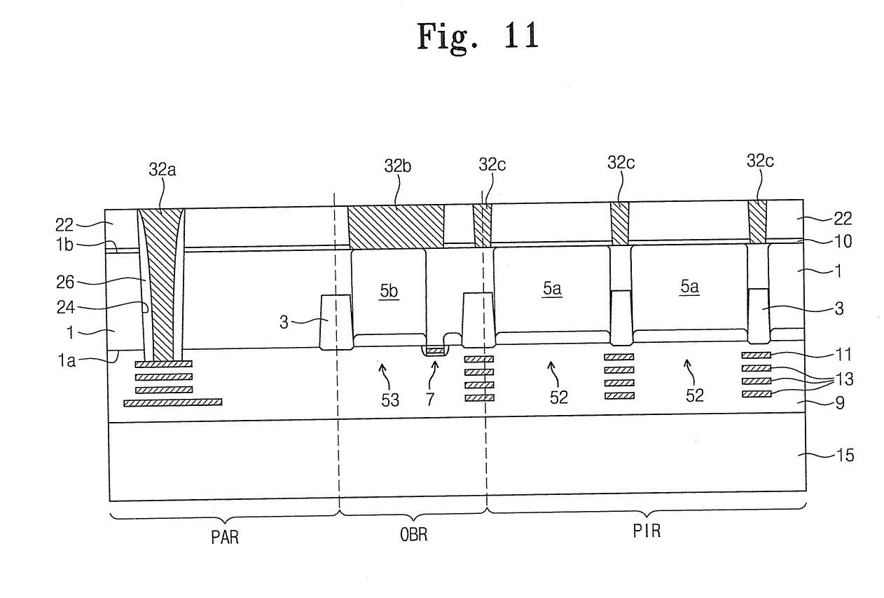

Referring to FIG. 11, a portion of the conductive layer 32 on the first dielectric layer 22 may be planarized to expose the first dielectric layer 22. A through via 32a, an optical black pattern 32b, and light shielding pattern 32c may be formed in the via hole 24, the optical black groove 30a, and the light shielding groove 30b, respectively. The planarization process may be one of a chemical mechanical polishing process and an etch-back process.

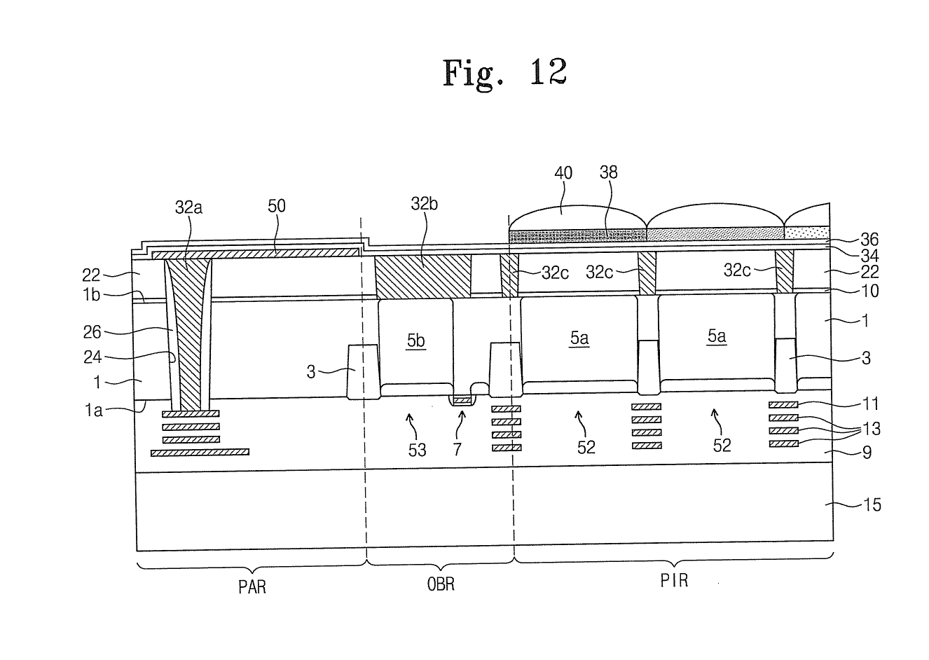

Referring to FIG. 12, a pad 50 may be formed to be in contact with an upper surface of the through via 32a. The pad 50 may be formed to include a metal layer, e.g., aluminum layer. A protective layer 34 and a planarization layer 36 may be formed on the second dielectric layer 22. The protective layer 34 and the planarization layer 36 may be formed to cover upper surfaces of the pad 50, the optical black pattern 32b, and the light shielding pattern 32c. A color filter 38 including a pigment may be formed to overlap each of the unit pixels 52 in the pixel region PIR. A micro lens 40 may be formed on the color filter 38. The micro lens 40 may be formed by, e.g., reflowing a photo resist pattern.

Referring back to FIG. 2, a portion of the protective layer 34 and a portion of the planarization layer 36 may be removed to expose the pad 50. A terminal 42, e.g., a solder ball or a bump, may be attached to the pad 50, thereby forming an image sensor illustrated in FIG. 2. According to example embodiments, the through via 32a, the optical black pattern 32b, and the light shielding pattern 32c may be formed in the same process, and this enables to simplify a manufacturing process. Also, this structure and method are advantageous to forming an image sensor having relatively high integration density. In detail, a dimension occupied by the pad 50 may be decreased, so that 2-dimensional size of an entire image sensor device or chip may be decreased.

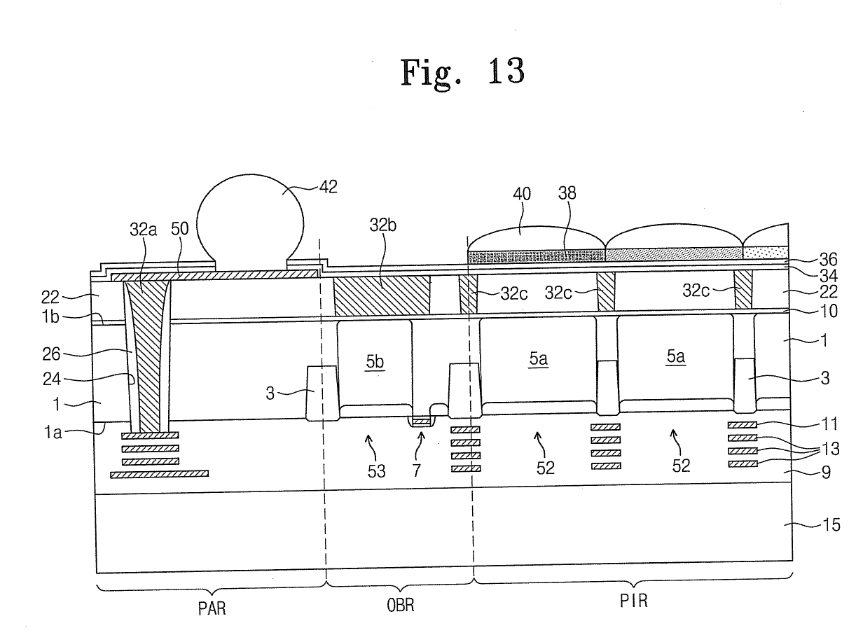

FIG. 13 is a cross-sectional view of an image sensor according to example embodiments taken along I-I′ line of FIG. 1.

Referring to FIG. 13, the optical black pattern 32b and the light shielding pattern 32c may penetrate the first dielectric layer 22 to contact an upper surface of the anti-refractive layer 10. That is, the optical black pattern 32b and the light shielding pattern 32c may not penetrate the anti-refractive layer 10 and be spaced apart from the substrate 1 without contacting the substrate 1.

The image sensor of FIG. 13 may be fabricated by etching the first dielectric layer 22 using the mask pattern 28 without etching the anti-refractive layer 10 to expose the anti-refractive layer 10 in a method step of FIG. 8. The anti-refractive layer 10 may be used as an etching stop layer. Other structures and methods of fabricating the structures may be substantially the same or similar to example embodiments.

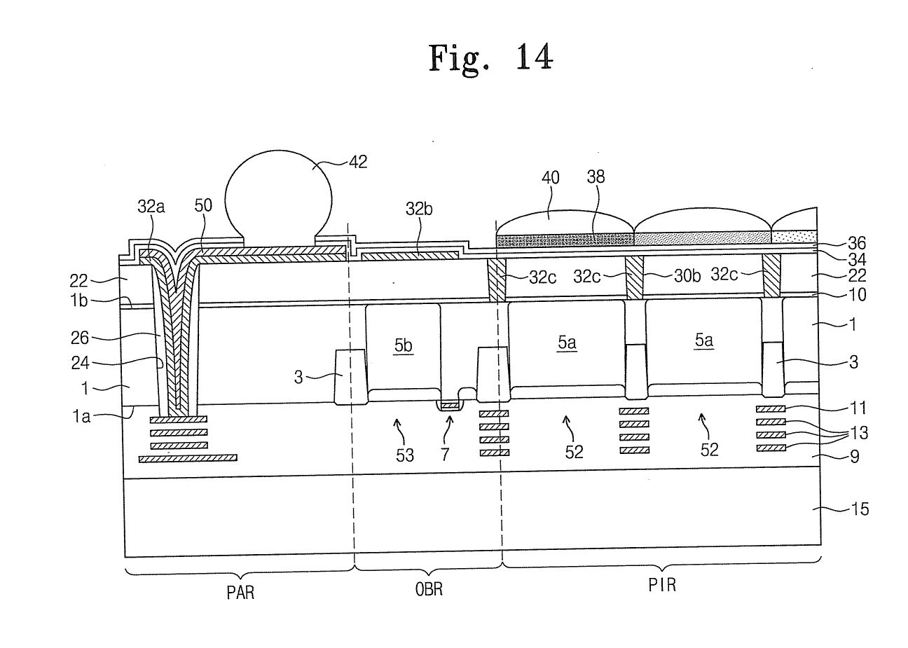

FIG. 14 is a cross-sectional view of an image sensor according to example embodiments taken along I-I″ line of FIG. 1.

Referring to FIG. 14, the through via 32a may cover a sidewall of the dielectric spacer 26 on a sidewall of the via hole 24 and the first interconnect 11 exposed at a bottom of the via hole 24 conformally. The through via 32a may not fill an entire space of the via hole 24. The through via 32a may extend to cover a portion of an upper surface of the first dielectric layer 22. The optical black pattern 32b may be disposed on the upper surface of the first dielectric layer 22 without penetrating the first dielectric layer 22. The light shielding pattern 32c may penetrate the anti-refractive layer 10 to contact the first surface 1b of the substrate 1. The through via 32a, the optical black pattern 32b, and the light shielding pattern 32c may include the same material. The pad 50 may be disposed on the through via 32a to fill the via hole 24. Other structures may be substantially the same or similar to example embodiments.

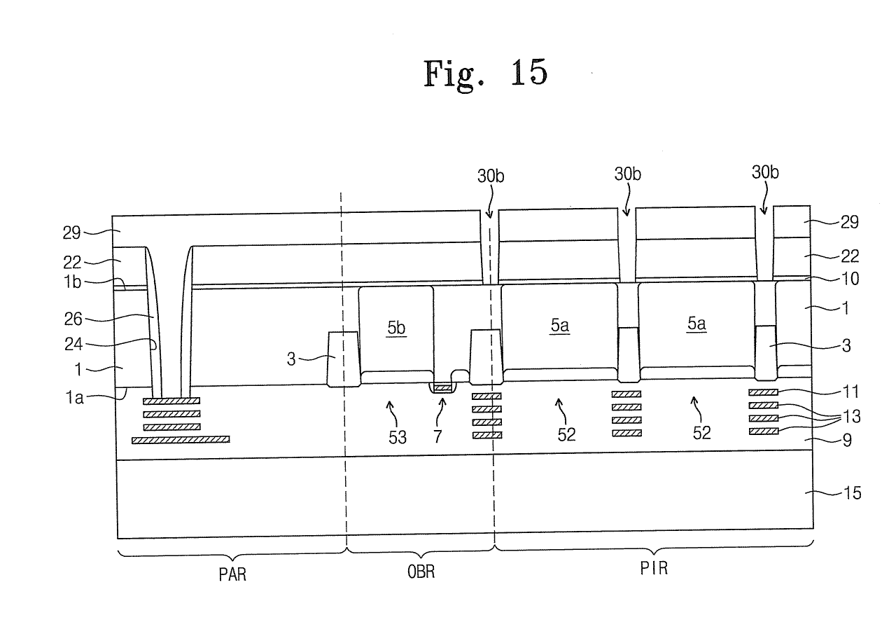

FIGS. 15 through 20 are cross-sectional views illustrating a method of fabricating the image sensor according to example embodiments.

Referring to FIG. 15, after forming the dielectric spacer 26 in the via hole 24 according to FIG. 6, a first mask pattern 29 may be formed on the first dielectric layer 22. The first mask pattern 29 may fill the via hole 24 and cover the pad region PAR and the optical black region OBR. The first mask pattern 29 may expose areas between the unit pixels 52 in the pixel region PIR. In example embodiments, the first mask pattern 29 may expose areas between the unit pixels 52 and the reference pixel 53. The first mask pattern 29 may be formed of, e.g., a photo resist pattern. The first dielectric layer 22 and the reflection inhibiting layer 10 may be sequentially etched using the first mask pattern 29 as an etching mask to form a light shielding groove 30b exposing the first surface 1b of the substrate 1 between the unit pixels 52. The light shielding groove 30b may have a grid shape in a plan view.

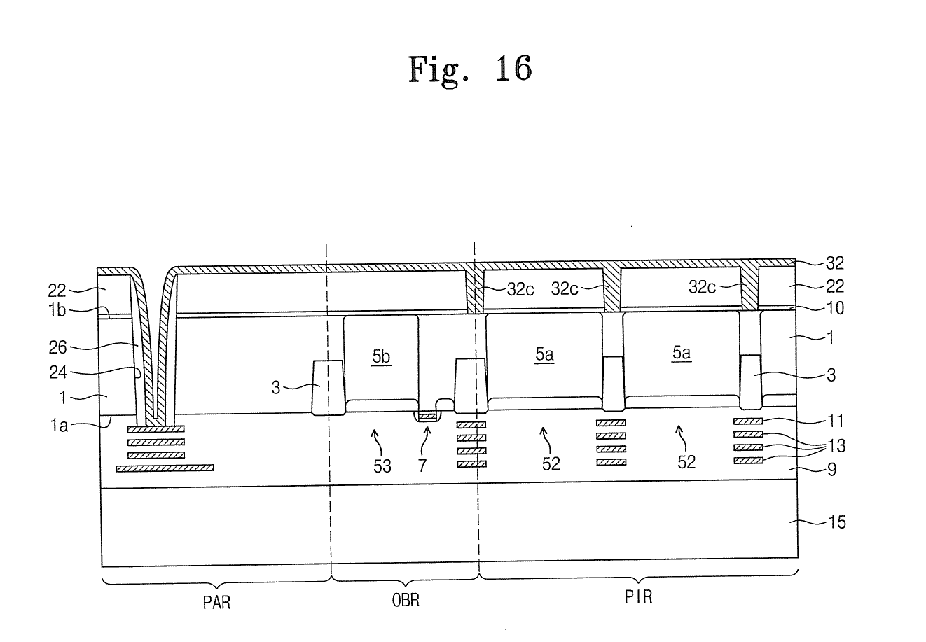

Referring to FIG. 16, the first mask pattern 29 may be removed to expose the upper surface of the first dielectric layer 22, the sidewall of the dielectric spacer 26, and an upper surface of the first conductive layer 11. When the first mask pattern 29 is made of a photo resist, the first mask pattern 29 may be removed by an ashing process. A conductive layer 32 may be formed conformally on the first surface 1b of the substrate 1. The conductive layer 32 may be formed to have a thickness at least to fill the light shielding groove 30b and form a light shielding pattern 32c.

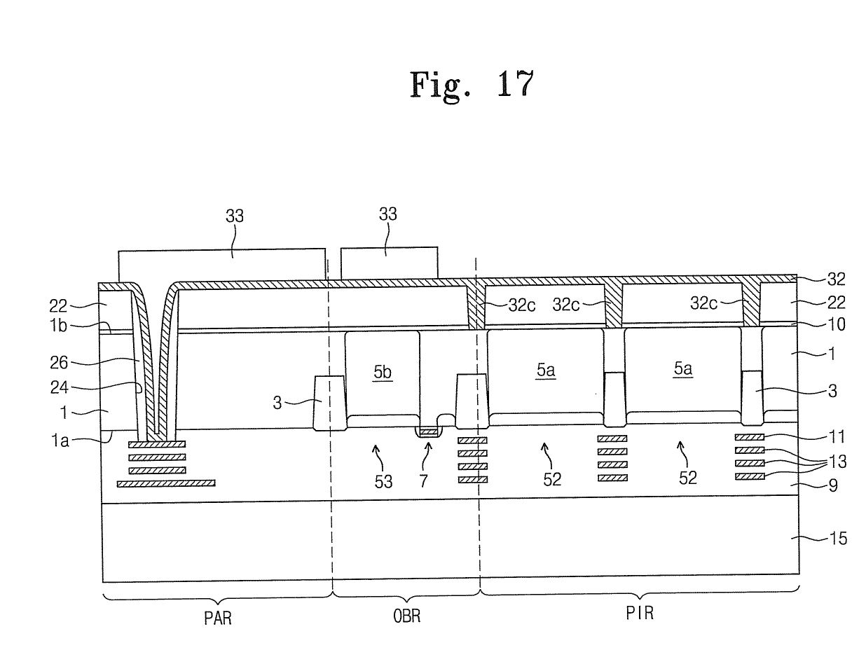

Referring to FIG. 17, a second mask pattern 33 may be formed on the conductive layer 32. The second mask pattern 33 may overlap at least the via hole 24 in the pad region PAR, define an optical black pattern described below in the optical black region OBR, and expose the pixel region PIR.

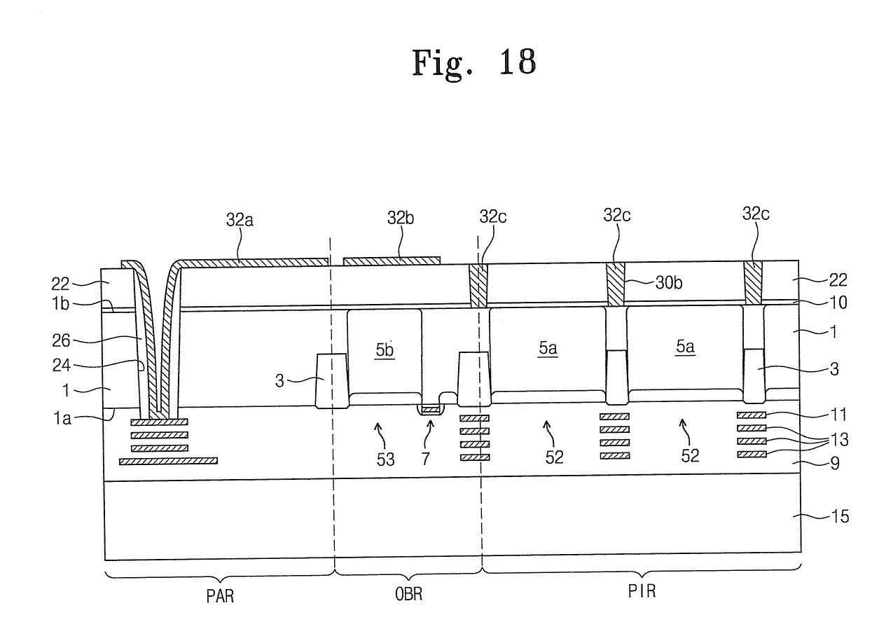

Referring to FIG. 18, the conductive layer 32 may be etched to expose the upper surface of the first dielectric layer 22 using the second mask pattern 33 as an etching mask. A through via 32a, an optical black pattern 32b, and a light shielding pattern 32c may be formed on the regions PAR, OBR, and PIR, respectively by the etching process. The light shielding pattern 32c may be disposed in the light shielding groove 30b and have a grid shape in a plan view. The through via 32a may extend on the upper surface of the first dielectric layer 22.

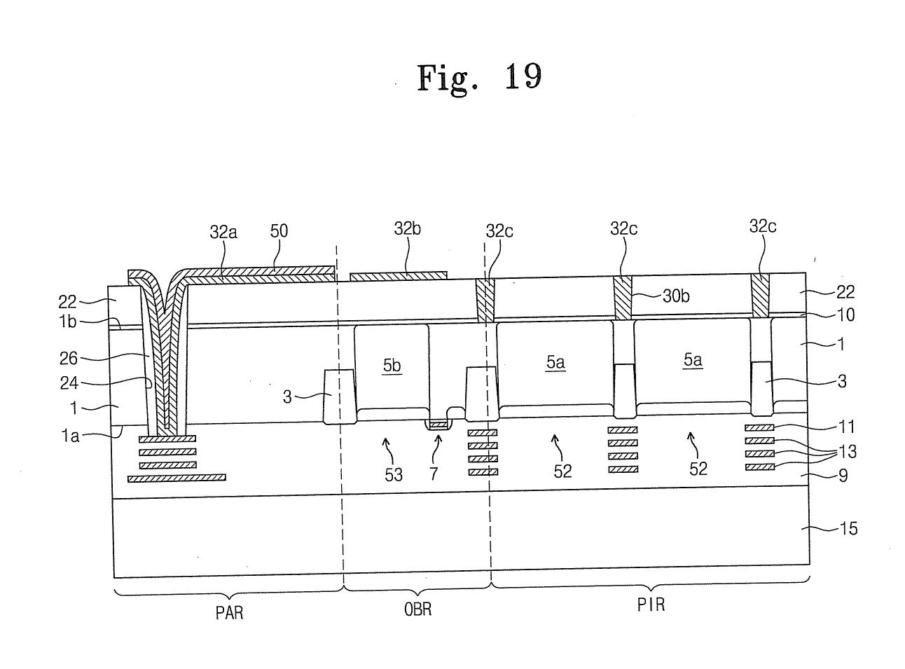

Referring to FIG. 19, a pad 50 may be foiined to overlap the through via 32a. A layer including metal, e.g., aluminum, may be disposed on the first dielectric layer 22 and selectively etched to form the pad 50. In example embodiments, the pad 50 may be formed by a plating process on the through via 32a.

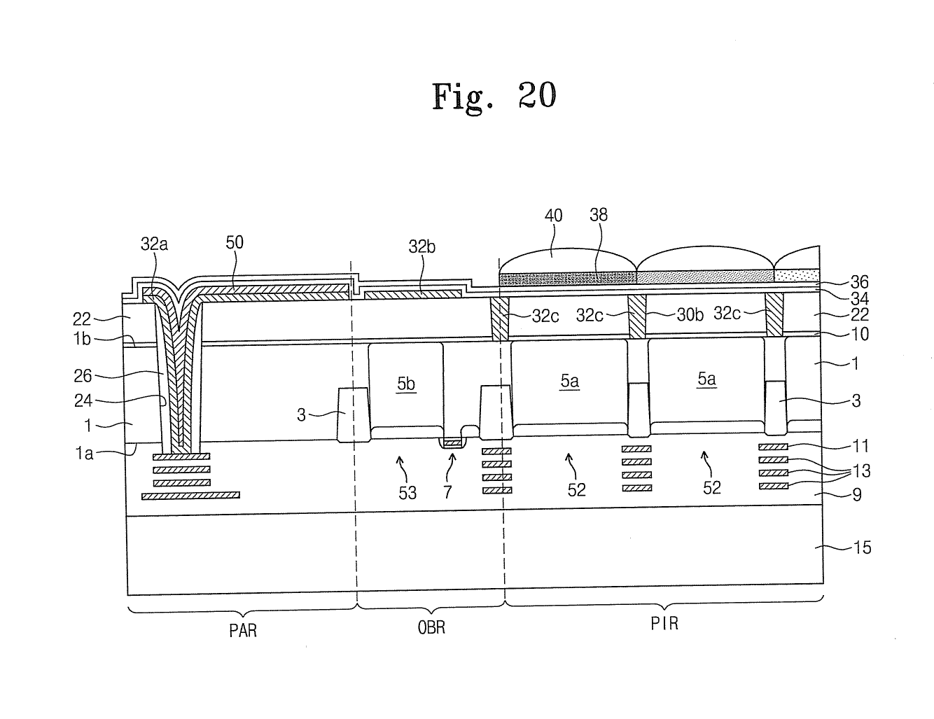

Referring to FIG. 20, a protective layer 34 and a planarization layer 36 may be formed on the first dielectric layer 22. For example, the protective layer 34 and the planarization layer 36 may cover the pad 50, the optical black pattern 32b, and the light shielding pattern 32c. A color filter 38 including a pigment may be formed to overlap each of the unit pixels 52 in the pixel region PIR. A micro lens 40 may be formed on the color filter 38. The micro lens 40 may be formed by, e.g., reflowing a photo resist pattern.

Referring back to FIG. 14, a portion of protective layer 34 and a portion of the planarization layer 35 may be removed to expose the pad 50. A terminal 42, e.g., a solder ball or a bump, may be attached to the exposed surface of the pad 50. Therefore, the image sensor illustrated in FIG. 14 may be fabricated. Additional steps of fabricating the structure may be substantially the same or similar to example embodiments.

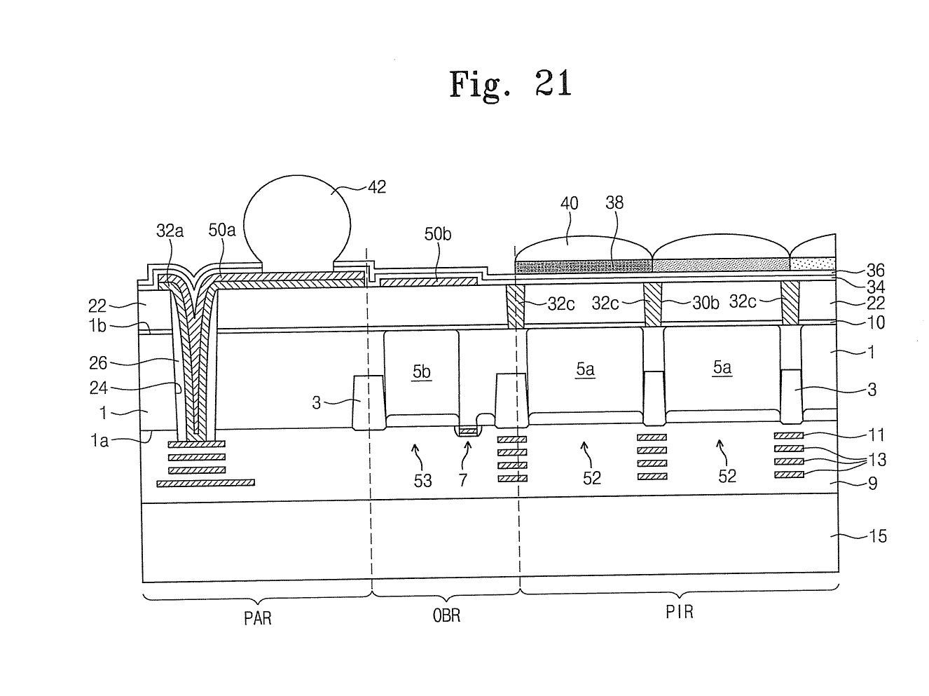

FIG. 21 is a cross-sectional view of an image sensor according example embodiments taken along I-I″ line of FIG. 1.

Referring to FIG. 21, the through via 32a and the light shielding pattern 32c may be formed of a material different from an optical black pattern 50b. The optical black pattern 50b may include the same material as a pad 50a.

The optical black pattern 50b may not formed in a same process with the through via 32a and the light shielding pattern 32c. The optical black pattern 50b may be formed in a same process with the pad 50a. A terminal 42 may penetrate the protective layer 34 and the planarization layer 36 to contact the pad 50a in the pad region PAR. Other structures and method of fabricating the structures may be substantially the same or similar to example embodiments.

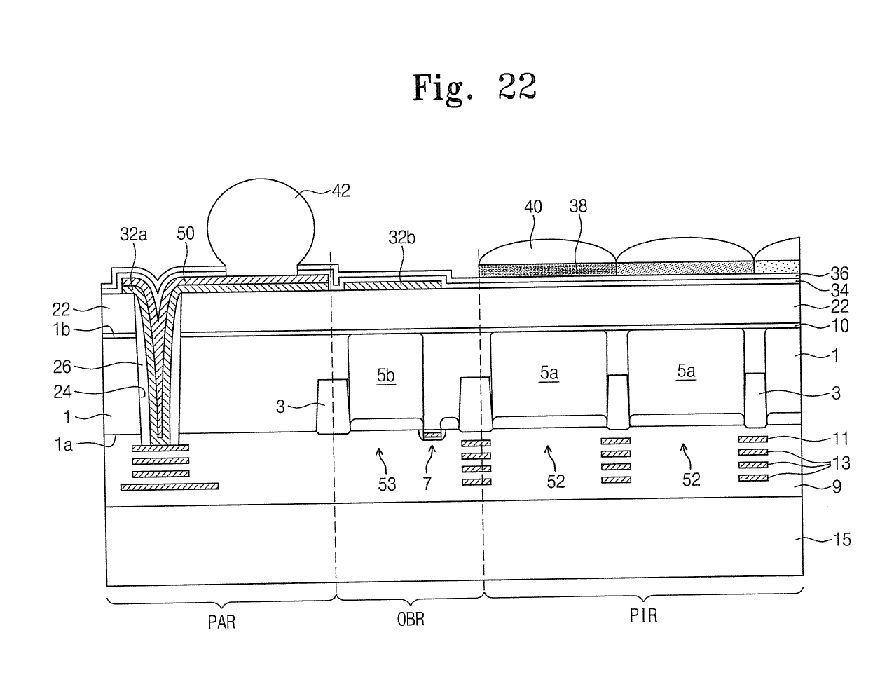

Referring to FIG. 22, the image sensor may not include a light shielding pattern between the unit pixels 52 in the pixel region PIR. The through via 32a and the optical black pattern 32b may include the same material and be formed in the same process. Other structures and methods of fabricating the structure may be substantially the same or similar to example embodiments.

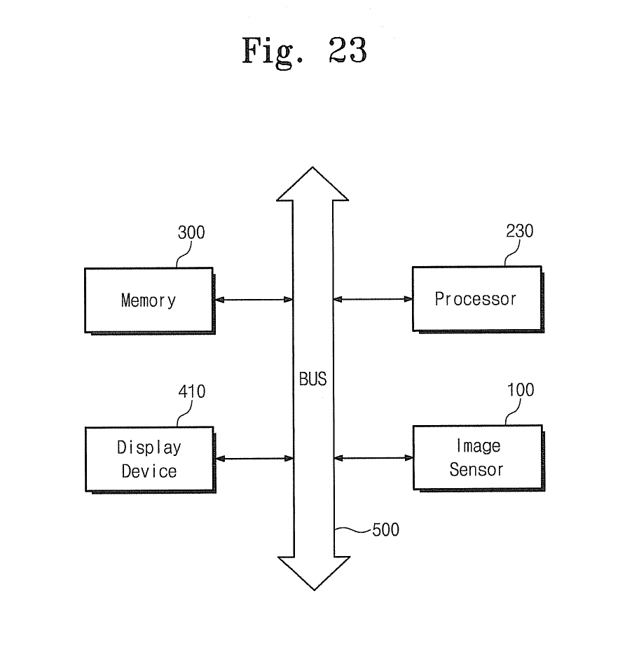

FIG. 23 is a block diagram illustrating an electronic device including an image sensor according to example embodiments. The electronic device may be, e.g., a digital camera or a mobile device.

Referring to FIG. 23, the device may include an image sensor 100, a processor 230, a memory 300, a display device 410, and a bus 500. The image sensor 100 may capture external visual information responding to a control signal from the processor 230. The processor 230 may store the captured visual information to the memory 300 through bus 500. The processor 230 may output the visual information stored in the memory to the display device 410.

According to example embodiments, cross-talk between the unit pixels may be prevented or reduced by the light shielding pattern between the unit pixels. According to example embodiments, the light shielding pattern, the optical black pattern, and a through via may be formed in the same process. Then, the manufacturing process of an image sensor may be simplified. According to example embodiments, a dimension occupied by the pad may be decreased, so that a two-dimensional size of an entire image sensor device or chip may be decreased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other example embodiments unless otherwise specifically indicated. Accordingly, it will be understood by those of skill in the art that various changes in form and details may be made without departing from the spirit and scope of the following claims.

What is claimed is:

1. An image sensor comprising:
a substrate including a pixel region and a pad region;
a through via configured to penetrate the substrate in the pad region;
a plurality of unit pixels in the pixel region; and
a light shielding pattern between the plurality of unit pixels,
wherein the through via and the light shielding pattern include a same material.

2. The image sensor as claimed in claim 1, wherein the light shielding pattern has a grid shape.

3. The image sensor as claimed in claim 1, further comprising:
an optical black region surrounding the pixel region of the substrate; and
an optical black pattern in the optical black region.

4. The image sensor as claimed in claim 3, wherein the optical black pattern includes the same material as the through via.

5. The image sensor as claimed in claim 3, wherein the substrate includes a first surface and a second surface opposite to the first surface, further comprising:
a first dielectric layer on the first surface,
wherein the light shielding pattern penetrates the first dielectric layer.

6. The image sensor as claimed in claim 5, wherein the optical black pattern is on the first dielectric layer.

7. The image sensor as claimed in claim 5, wherein the optical black pattern penetrates the first dielectric layer.

8. The image sensor as claimed in claim 5, wherein the through via extends to penetrate the first dielectric layer, further comprising:
a pad configured to contact the through via on the first dielectric layer.

9. The image sensor as claimed in claim 5, further comprising:
an anti-refractive layer between the first dielectric layer and the substrate,
wherein the light shielding pattern and the optical black pattern are configured to penetrate the anti-refractive layer and contact the substrate.

10. The image sensor as claimed in claim 5, further comprising:
a second dielectric layer on the second surface; and
a plurality of interconnects in the second dielectric layer,
wherein the through via is configured to penetrate the first dielectric layer, the substrate, and a portion of the second dielectric layer to be electrically connected to the plurality of interconnects.

11. The image sensor as claimed in claim 10, wherein the through via contacts an interconnect of the plurality of interconnects nearest to the second surface.

12. The image sensor as claimed in claim 5, further comprising:
a reference pixel in the substrate in the optical black region,
wherein the optical black pattern is configured to overlap the reference pixel.

13. The image sensor as claimed in claim 5, further comprising:
a plurality of transistors on the second surface,
wherein light is incident to the first surface.

14. The image sensor as claimed in claim 1, further comprising:
a device isolation layer in the pixel region of the substrate, the device isolation layer separating the plurality of unit pixels,
wherein the light shielding pattern overlaps the device isolation layer in a vertical direction when viewed from a cross-sectional view.

15. An image sensor comprising:
a substrate including an optical black region and a pad region;
a through via penetrating the substrate in the pad region; and
an optical black pattern in the optical black region,
wherein the optical black pattern and the through via include a same material.

16. An image sensor comprising:
a substrate including a pixel region and a pad region;
a through via configured to penetrate the substrate in the pad region;
a plurality of unit pixels in the pixel region; and
an isolation structure including a light shielding pattern and a device isolation layer separating the plurality of unit pixels,
wherein the light shielding pattern overlaps the device isolation layer in a vertical direction in a cross-sectional view.

17. The image sensor as claimed in claim 16, wherein the light shielding pattern has a grid shape.

18. The image sensor as claimed in claim 16, wherein the through via and the light shielding pattern include a same material.

19. The image sensor as claimed in claim 18, further comprising:
an optical black region surrounding the pixel region of the substrate; and
an optical black pattern in the optical black region.

20. The image sensor as claimed in claim 19, wherein the optical black pattern includes the same material as the through via and the light shielding pattern.
